(19) United States
(12) Patent Application Publication
(10) Pub. No.: US 2016/0190353 A1
(43) Pub. Date: Jun. 30, 2016

(54) PHOTOSENSITIVE MODULE AND METHOD FOR FORMING THE SAME

(71) Applicant: XINTEC INC., Taoyuan City (TW)

(72) Inventors: Chi-Chang LIAO, Pingtung City (TW); Po-Chang HUANG, New Taipei City (TW); Tsang-Yu LIU, Zhubei City (TW)

(21) Appl. No.: 14/860,388

(22) Filed: Sep. 21, 2015

Related U.S. Application Data
(60) Provisional application No. 62/096,993, filed on Dec. 26, 2014.

(51) Int. Cl. H01L 31/02; H01L 31/0203; H01L 31/0232

(52) U.S. Cl. CPC H01L 31/02005; H01L 31/02327; H01L 31/0203

(57) ABSTRACT

A method for forming a photosensitive module is provided. The method includes providing a substrate having a first surface and a second surface opposite thereto. A conducting pad is located on the first surface. A cover plate is provided on the first surface of the substrate. An opening is formed. The opening penetrates the substrate and exposes the conducting pad. A redistribution layer is formed in the first opening to electrically connect to the conducting pad. The cover plate is removed and a dicing process is performed to form a sensing device. The sensing device is bonded to a circuit board. An optical component is mounted on the circuit board and corresponds to the sensing device. A photosensitive module formed by the method is also provided.

### CROSS REFERENCE TO RELATED APPLICATIONS

This application is based on, and claims priority of U.S. Provisional Application No. 62/096,993, filed Dec. 26, 2014, the entirety of which is incorporated by reference herein.

### BACKGROUND OF THE INVENTION

1. Field of the Invention

The invention relates to a photosensitive module and methods for forming the same, and in particular to a photosensitive module with a sensing device formed by a wafer-level packaging process.

2. Description of the Related Art

A camera module is usually fabricated by chip on board (COB) technology. For example, a die is directly attached onto a printed circuit board (PCB) by adhesive glue. The die is electrically connected to the PCB by wire bonding processes. Next, a lens and a holder are mounted on the PCB.

However, it is necessary to press the die in order for it to be successfully attached to the PCB, using COB technology. As a result, it is difficult to reduce the thickness of the die. Otherwise, physical damage may be incurred. Furthermore, performing wire bonding processes to construct an electrically conductive path is necessary for the COB technology. The aforementioned fabrication process needs to be carried out in a clean environment, such as a clean room, to ensure the quality and yield of the camera module. Accordingly, the fabrication cost is high.

Thus, there exists a need to develop a novel photosensitive module and methods for forming the same, capable of mitigating or eliminating the aforementioned problems.

### BRIEF SUMMARY OF THE INVENTION

An embodiment of the invention provides a method for forming a photosensitive module. The method comprises providing a substrate having a first surface and a second surface opposite thereto. A conducting pad is located on the first surface. A cover plate is provided on the first surface of the substrate. A first opening is formed. The first opening penetrates the substrate and exposes the conducting pad. A redistribution layer is formed in the first opening. The redistribution layer is electrically connected to the conducting pad. The cover plate is removed and subsequently a dicing process is performed to form a sensing device. The sensing device is bonded to a circuit board. An optical component is mounted on the circuit board and corresponds to the sensing device.

An embodiment of the invention provides a photosensitive module comprising a sensing device. The sensing device comprises a substrate having a first surface and a second surface opposite thereto. A conducting pad is disposed on the first surface. An anti-contamination layer is disposed on the first surface of the substrate and covers the conducting pad. A first opening penetrates the substrate and exposes the conducting pad. A redistribution layer is disposed in the first opening to electrically connect to the conducting pad. The sensing device is bonded onto a circuit board. An optical component corresponds to the sensing device and is mounted on the circuit board.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A to 1G are cross-sectional views of an exemplary embodiment of a method for forming a photosensitive module according to the invention.

FIGS. 2A to 2D are cross-sectional views of another exemplary embodiment of a method for forming a photosensitive module according to the invention.

FIGS. 3A to 3D are cross-sectional views of yet another exemplary embodiment of a method for forming a photosensitive module according to the invention.

FIGS. 4A to 4G are cross-sectional views of yet another exemplary embodiment of a method for forming a photosensitive module according to the invention.

FIGS. 5A to 5B are cross-sectional views of yet another exemplary embodiment of a method for forming a photosensitive module according to the invention.

FIGS. 6 and 7 are top views of various exemplary embodiments of a partial substrate according to the invention.

FIG. 8 is a cross-sectional view of yet another exemplary embodiment of a photosensitive module according to the invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. The disclosed contents of the present disclosure include all the embodiments derived from claims of the present disclosure by those skilled in the art. In addition, the present disclosure may repeat reference numbers and/or letters in the various embodiments. This repetition is for the purpose of simplicity and clarity, and does not imply any relationship between the different embodiments and/or configurations discussed. Furthermore, when a first layer is referred to as being on or overlying a second layer, the first layer may be in direct contact with the second layer, or spaced apart from the second layer by one or more material layers.

A chip package according to an embodiment of the present invention may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, microfluidic systems, and physical sensors measuring changes to physical quantities such as heat, light, capacitance, pressure, and so on. In particular, a wafer-level packaging (WSP) process may optionally be used to package semiconductor chips, such as image-sensor elements, light-emitting diodes (LEDs), solar cells, RF circuits, accelerators, gyroscopes, fingerprint recognition devices, microactuators, surface acoustic wave devices, pressure sensors, ink printer heads, and so on.

The above-mentioned wafer-level packaging process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level packaging process. In addition, the above-mentioned wafer-level packaging process may also be adapted to form a chip package having multilayer integrated circuit devices by stacking a plurality of wafers having integrated circuits.

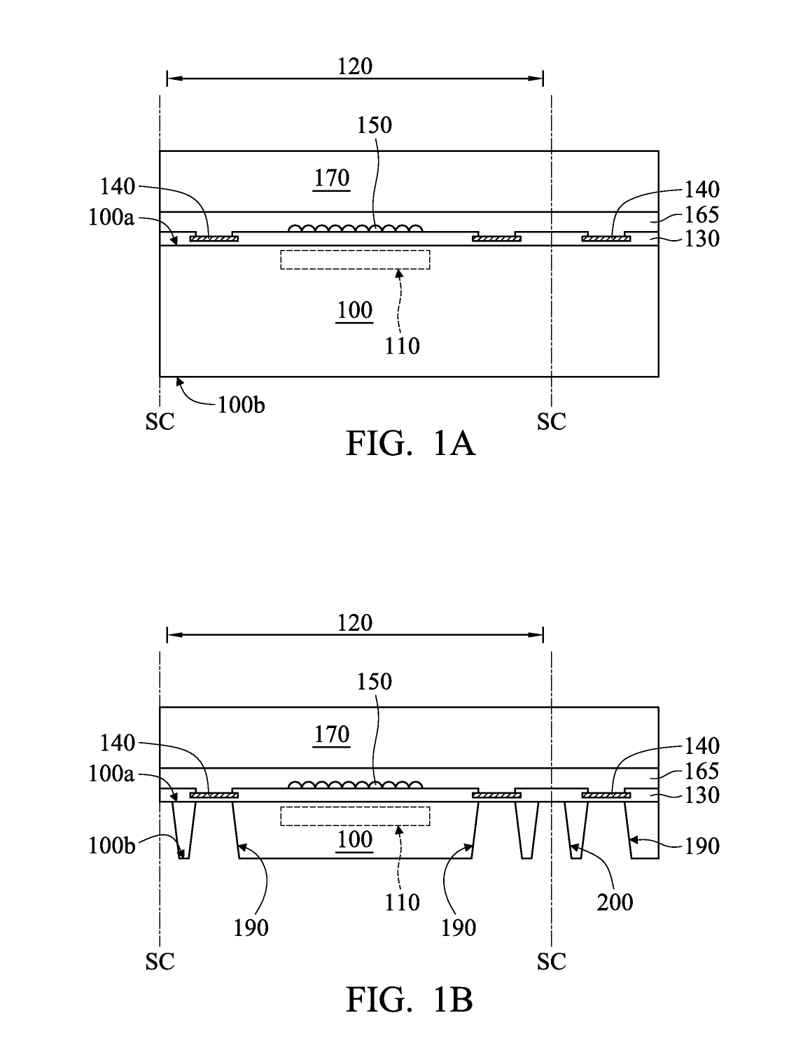

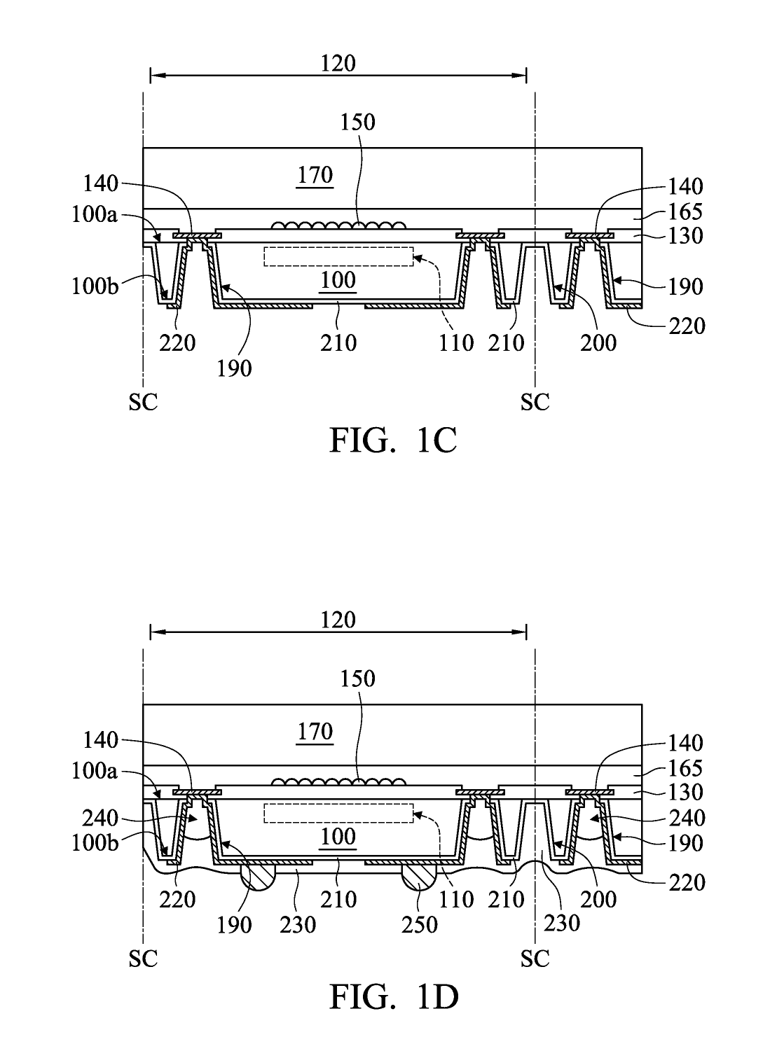

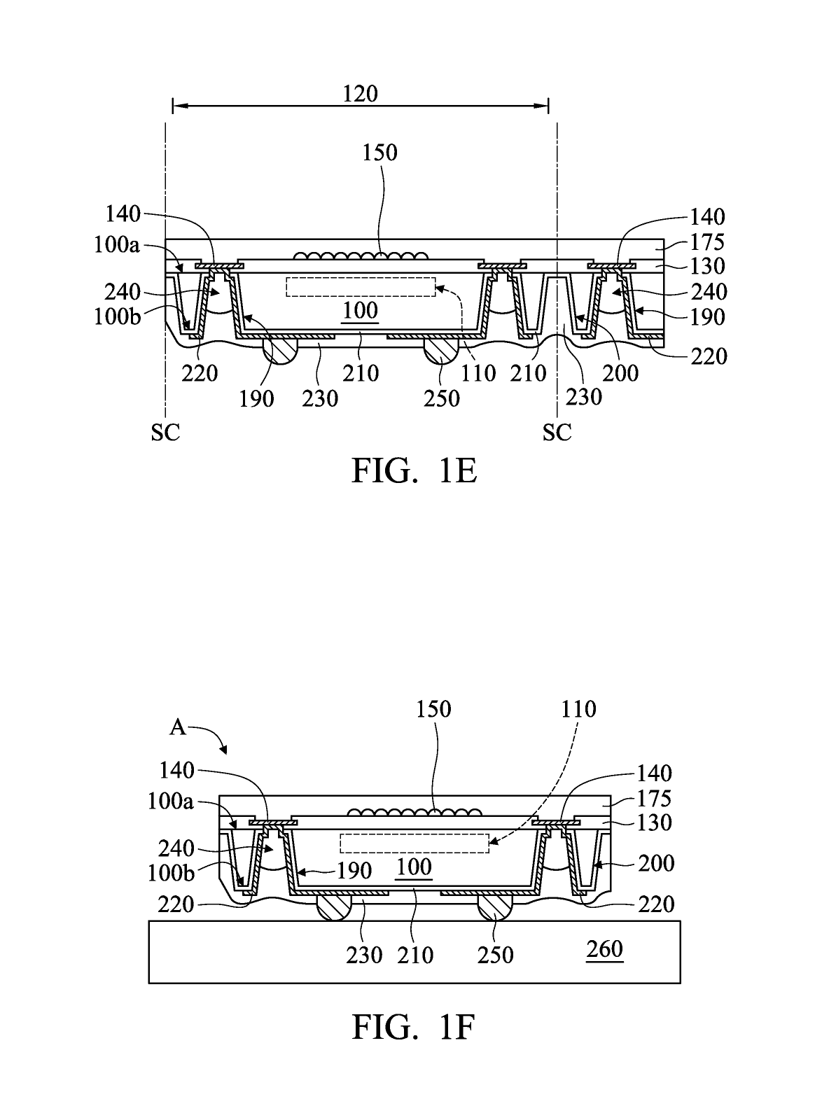

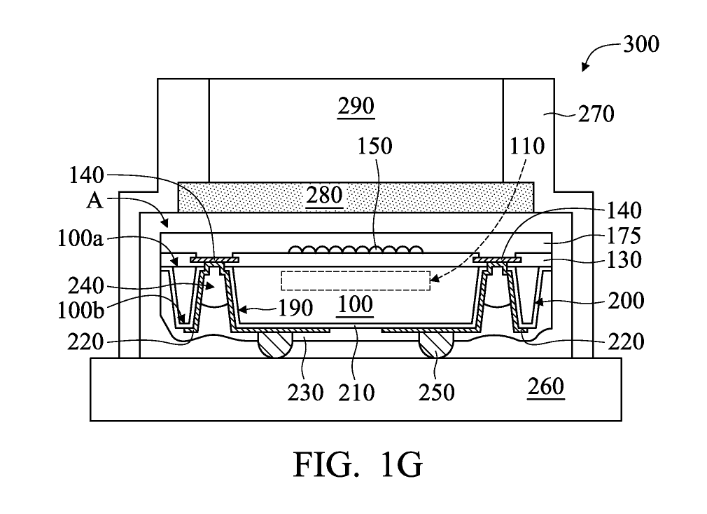

Referring to FIG. 1G, a cross-sectional view of an exemplary embodiment of a photosensitive module 300 according to the invention is illustrated. The photosensitive module 300 comprises a circuit board 260, a sensing device A and an optical component. In the embodiment, the sensing device A comprises a substrate 100, conducting pads 140, first openings 190, an anti-contamination layer 175 and a redistribution layer (RDL) 220. The substrate 100 has a first surface 100a and a second surface 100b opposite thereto. In one embodiment, the substrate 100 may be a silicon substrate or another semiconductor substrate.

There is an insulating layer 130 on the first surface 100a of the substrate 100. In general, the insulating layer 130 may be made of an interlayer dielectric (ILD) layer, inter-metal dielectric (IMD) layers and a covering passivation layer. To simplify the diagram, only a single insulating layer 130 is depicted herein. In other words, the sensing device A comprises a chip/die, and the chip/die comprises the substrate 100 and the insulating layer 130. In the embodiment, the insulating layer 130 may comprise an inorganic material, such as silicon oxide, silicon nitride, silicon oxynitride, metal oxide, another suitable insulating material or a combination thereof.

In the embodiment, one or more conducting pads 140 are in the insulating layer 130 on the first surface 100a of the substrate 100. In one embodiment, the conducting pads 140 may be a single conducting layer or comprise multiple conducting layers. To simplify the diagram, only two conducting pads 140 comprising a single conducting layer in the insulating layer 130 are depicted herein as an example. In the embodiment, the insulating layer 130 comprises one or more openings exposing the corresponding conducting pads 140.

In the embodiment, the sensing device A further comprises a sensing or device region 110 and an optical element 150. The sensing or device region 110 may be adjacent to the first surface 100a of the substrate 100, and may be electrically connected to the conducting pads 140 through interconnection structures (not shown). The sensing or device region 110 may comprise an image sensing element. For example, the sensing device may be a complementary metal oxide semiconductor (CMOS) image sensing device or another suitable image sensing device. Furthermore, the optical element 150 is disposed on the first surface 100a of the substrate 100 and corresponds to the sensing or device region 110. In the embodiment, the optical element 150 may be a micro-lens array or another suitable optical element used for an image sensing device.

In the embodiment, the anti-contamination layer 175 is disposed on the first surface 100a of the substrate 100, and covers the exposed conducting pads 140 and the exposed optical element 150 to prevent the optical element 150 and the sensing or device region 110 from being contaminated by the external environment. For example, the anti-contamination layer 175 can avoid dust or moisture intrusion into the optical element 150 and the sensing or device region 110. In the embodiment, the anti-contamination layer 175 may be made of a light-transmissive insulating material, such as a polymer material. In one embodiment, the thickness of the anti-contamination layer 175 may be in a range from 50 μm to 200 μm.

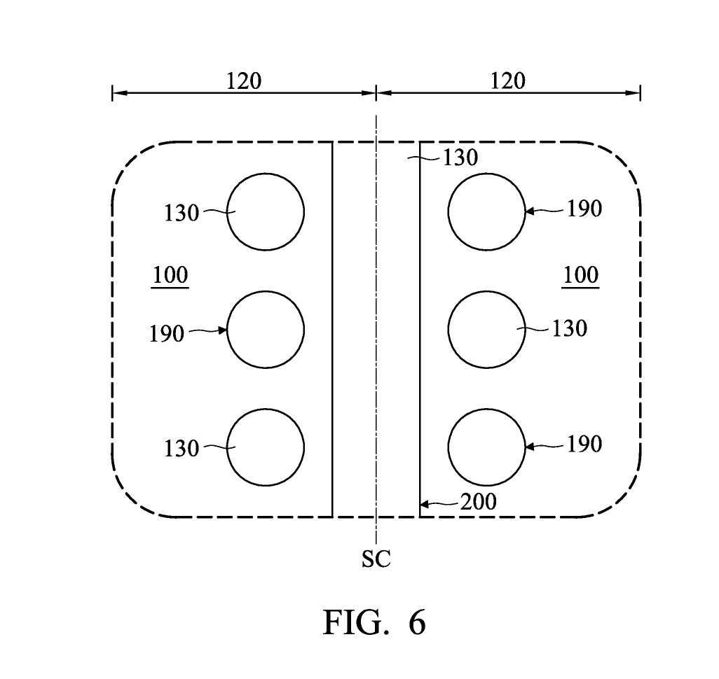

The first openings 190 penetrate the substrate 100 and extend into the insulating layer 130, and thereby exposing the corresponding conducting pads 140 from the second surface 100b of the substrate 100. In the embodiment, the diameter of the first opening 190 adjacent to the first surface 100a is less than that of the first opening 190 adjacent to the second surface 100b. As a result, the first openings 190 have inclined sidewalls. In the embodiment, the sensing device A further comprises a second opening 200, which extends along the sidewall of the substrate 100 and penetrates the substrate 100. Namely, the substrate 100 has retracted edge sidewalls. Furthermore, multiple first openings 190 are spaced apart along the second opening 190, as shown in FIG. 6, wherein FIG. 6 is a top view of a partial substrate 100. In one embodiment, the second opening 200 may extend along all the sidewalls of the substrate 100 and surround the first openings 190. In the embodiment, the top-view profile of the first openings 190 is different from that of the second opening 200. For example, the top-view profile of the first openings 190 is circular while the top-view profile of the second opening 200 is rectangular, as shown in FIG. 6. It should be noted that the top-view profiles of the first openings 190 and the second opening 200 may be another shape, and they are not limited thereto.

An insulating layer 210 is disposed on the second surface 100b of the substrate 100. The insulating layer 210 conformally extends to the sidewalls of the first opening 190 and the sidewalls and the bottom of the second opening 200, and exposes the conducting pads 140. In the embodiment, the insulating layer 210 may comprise epoxy resin, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates) or another suitable insulating material.

The patterned redistribution layer 220 is disposed on the second surface 100b of the substrate 100. The redistribution layer 220 conformally extends to the sidewalls and the bottom of the first opening 190 without extending into the second opening 200. The redistribution layer 220 may be electrically isolated from the substrate 100 by the insulating layer 210. The redistribution layer 220 may be in direct electrical contact with or indirectly electrically connected to the exposed conducting pads 140 through the first openings 190. As a result, the redistribution layer 220 in the first openings 190 is also referred to as a through silicon via (TSV). In one embodiment, the redistribution layer 220 may comprise aluminum, copper, gold, platinum, nickel, tin, a combination thereof, a conductive polymer material, a conductive ceramic material (such as indium tin oxide or indium zinc oxide), or another suitable conductive material.

A protection layer 230 is disposed on the second surface 100b of the substrate 100, and fills the first openings 190 and the second opening 200 to cover the redistribution layer 220. In the embodiment, the protection layer 230 has an uneven surface. In one embodiment, the protection layer 230 may comprise epoxy resin, solder mask, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates), or another suitable insulating material.

In the embodiment, the first openings 190 are not fully filled with the protection layer 230, so that a hole 240 is formed between the redistribution layer 220 and the protection layer 230 within the first openings 190. Since the protection layer 230 partially fills the first openings 190 and leaves the hole 240, the hole 240 can be a buffer between the redistribution layer 220 and the protection layer 230 in thermal cycles induced in subsequent processes. Undesirable stress, which is induced between the redistribution layer 220 and the protection layer 230 as a result of mismatch of thermal expansion coefficients, is reduced. The redistribution layer 220 is prevented from being excessively pulled by the protection layer 230 when external temperature or pressure dramatically changes. As a result, peeling or disconnection problems of the redistribution layer 220, which is close to the conducting pad structure, are avoidable. In one embodiment, the interface between the protection layer 230 and the hole 240 has an arcuate contour.

The protection layer 230 on the second surface 100b of the substrate 100 has openings exposing portions of the redistribution layer 220. Furthermore, a plurality of conducting structures 250 (such as solder balls, bumps or conductive pillars) are disposed in the openings of the protection layer 230 to electrically connect to the exposed redistribution layer 220. In one embodiment, the conducting structures 250 may comprise tin, lead, copper, gold, nickel, or a combination thereof.

In the embodiment, the sensing device A is bonded to the circuit board 260, and is electrically connected to the circuit board 260 through the conducting structures 250 on the second surface 100b of the substrate 100. Furthermore, an optical component of the photosensitive module 300 corresponds to the sensing device A and is mounted on the circuit board 260. As a result, the anti-contamination layer 175 is located between the optical component and the first surface 100a of the substrate 100.

In the embodiment, the optical component comprises a holder 270, a filter 280 and a lens 290. The holder 270 has a capacity space, so that the filter 280 and the lens 290 are disposed within the capacity space of the holder 270 and are fixed to the holder 270. Therefore, the photosensitive module 300 is a fixed-focus device. The capacity space of the holder 270 can further accommodate the sensing device A on the circuit board 260. The filter 280 in the capacity space is located between the lens 290 and the sensing device A so as to filter out infrared irradiation in light, which irradiates through the lens 290 towards the sensing device A. In one embodiment, the filter 280 is made of a light-transmissive material (such as glass) and a filter layer thereon. Furthermore, the lens 290 can be formed of a single lens set or comprise multiple lens sets. To simplify the diagram, only flat filter 280 and lens 290 are depicted herein. The structure of the optical component is determined by design requirements and is not limited thereto.

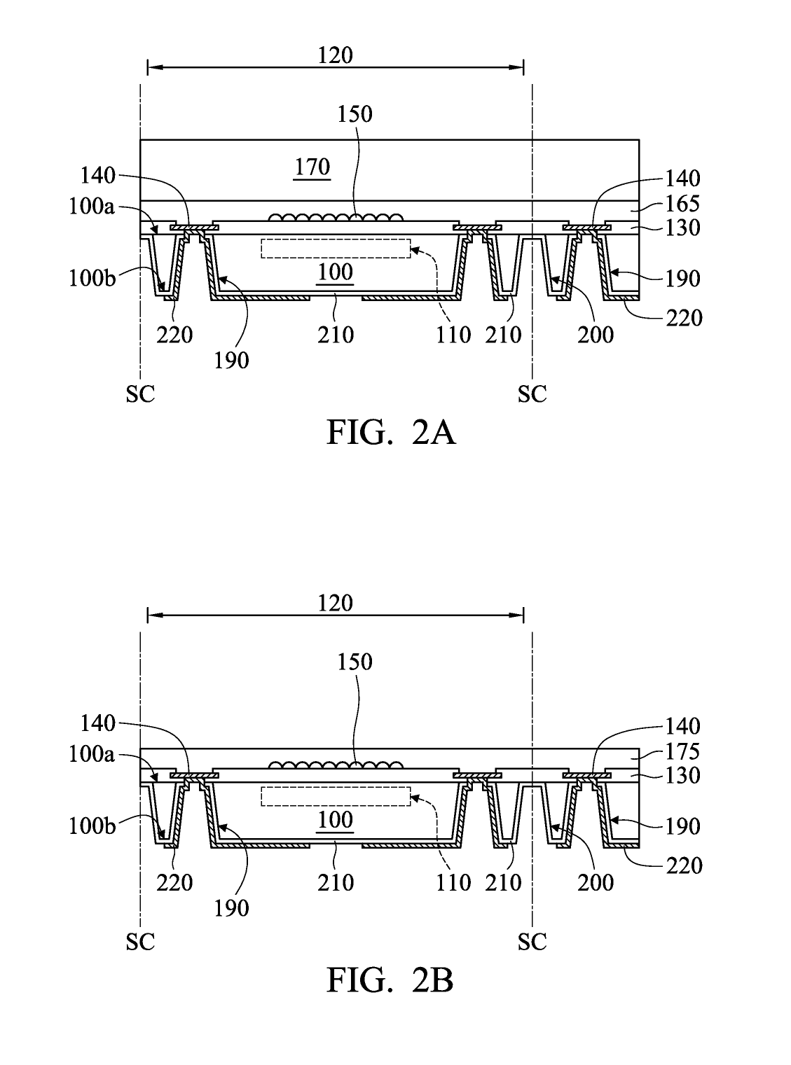

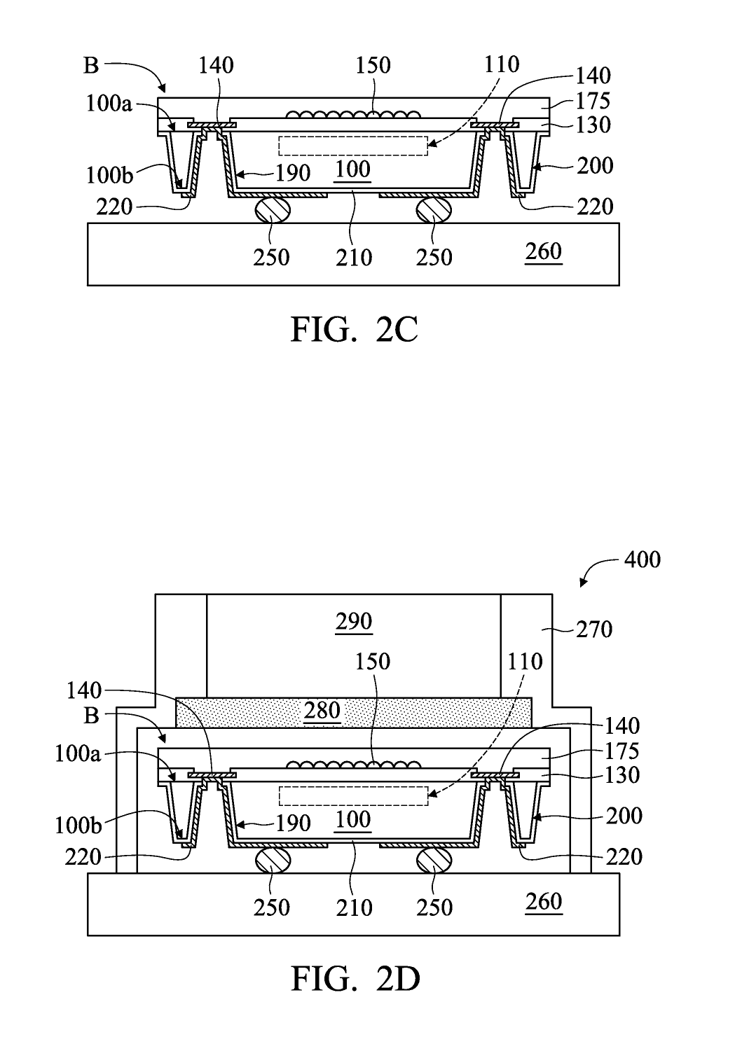

Referring to FIGS. 2D, 3D, 4G, 5B, and 8, cross-sectional views of other exemplary embodiments of photosensitive modules 400, 500, 600, 700, and 800 according to the invention is respectively illustrated. Elements in FIGS. 2D, 3D, 4G, 5B, and 8 that are the same as those in FIG. 1G are labeled with the same reference numbers as in FIG. 1G and are not described again for brevity.

The structure of the photosensitive module 400 shown in FIG. 2D is similar to that of the photosensitive module 300 shown in FIG. 1G. The difference therebetween is that there is a protection layer 230 on the second surface 100b of the substrate 100 in the photosensitive module 300 to cover the redistribution layer 220. In contrast, there is no protection layer on the second surface 100b of the substrate 100 in the photosensitive module 400, and the redistribution layer 220 is completely exposed. Furthermore, the conducting structures 250 in the photosensitive module 300 are solder balls, bumps or conductive pillars, while the conducting structures 250 in the photosensitive module 400 are solder bumps, bonding pads or conductive adhesive glue. The size of the conducting structures 250 in the photosensitive module 300 is less than that of the conducting structures 250 in the photosensitive module 400.

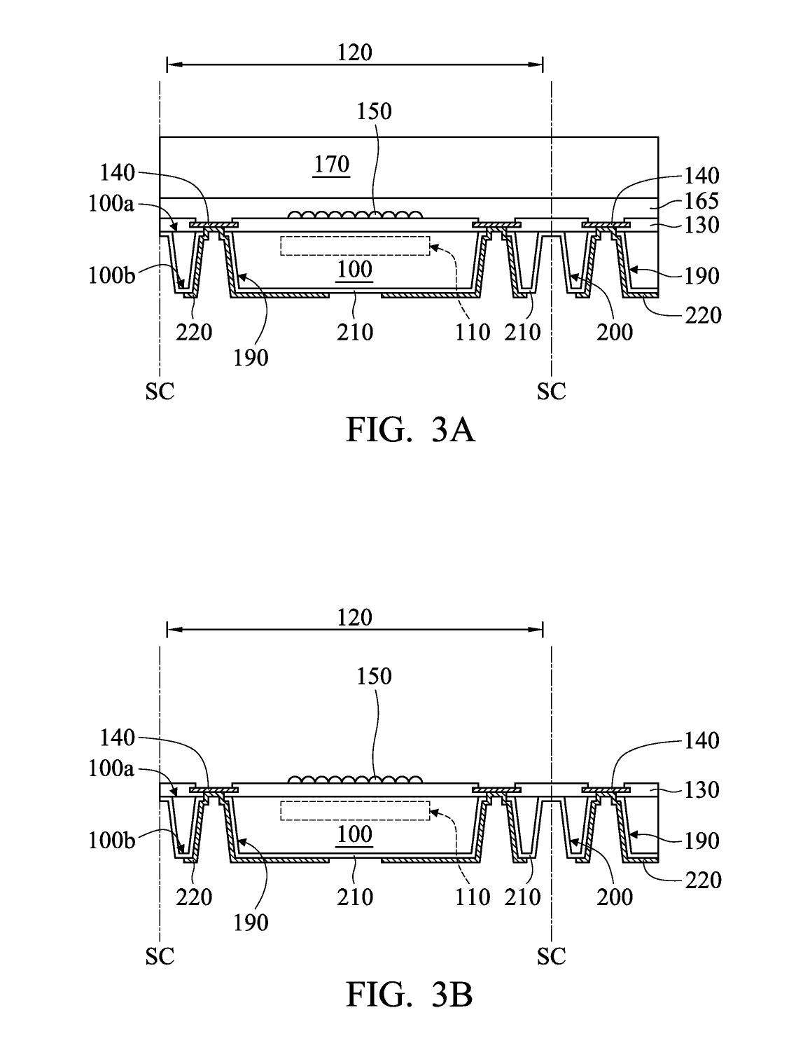

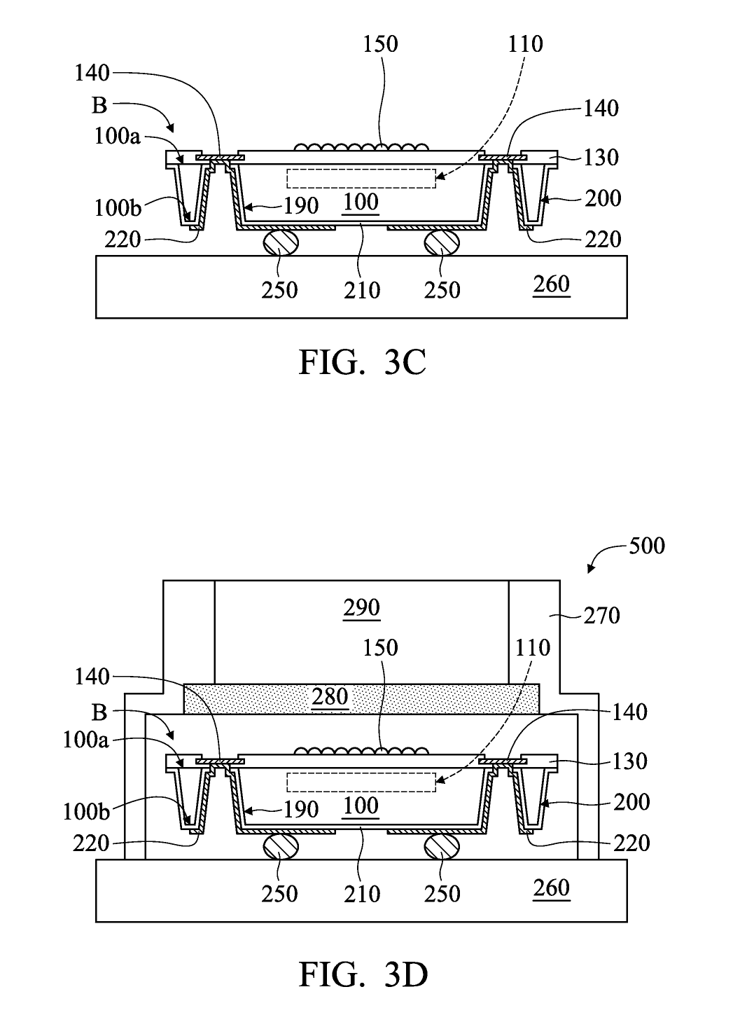

The structure of the photosensitive module 500 shown in FIG. 3D is similar to that of the photosensitive module 400 shown in FIG. 2D. The difference therebetween is that there is an anti-contamination layer 175 on the first surface 100a of the substrate 100 in the photosensitive module 400 to cover the optical element 150 and the sensing or device region 110. In contrast, there is no anti-contamination layer on the first surface 100a of the substrate 100 in the photosensitive module 500, and the optical element 150 and the conducting pads 140 are exposed.

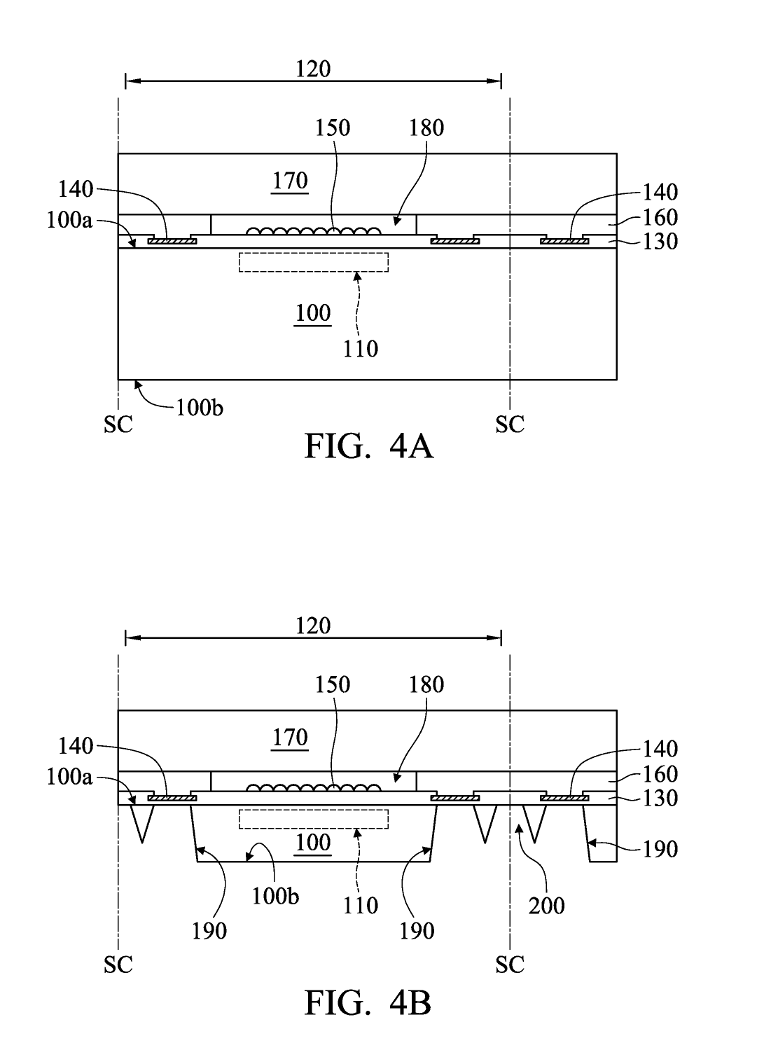

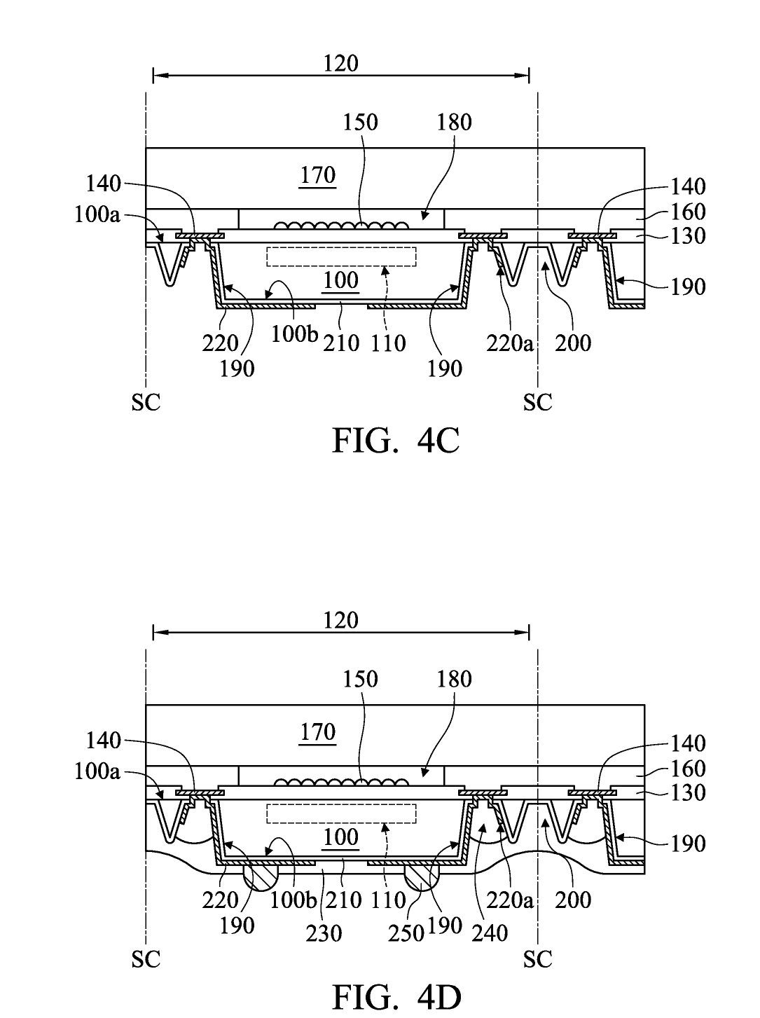

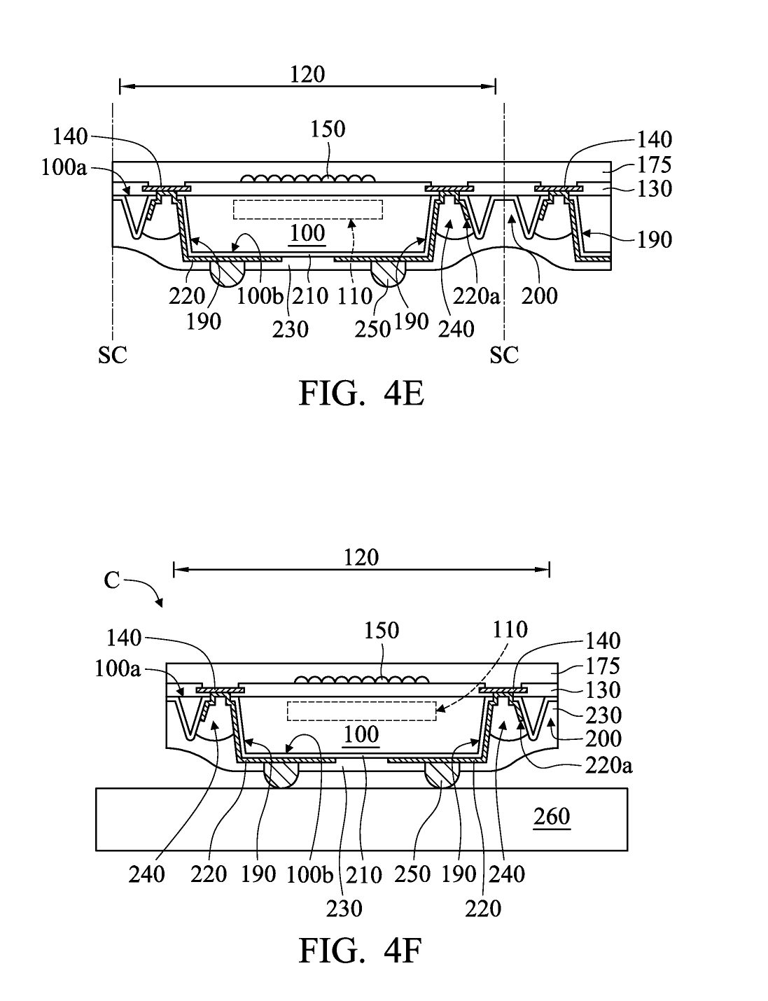

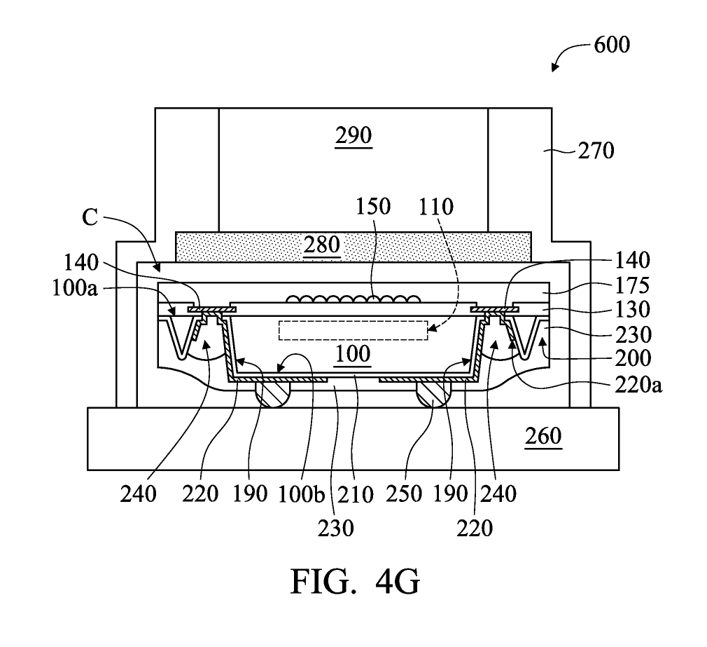

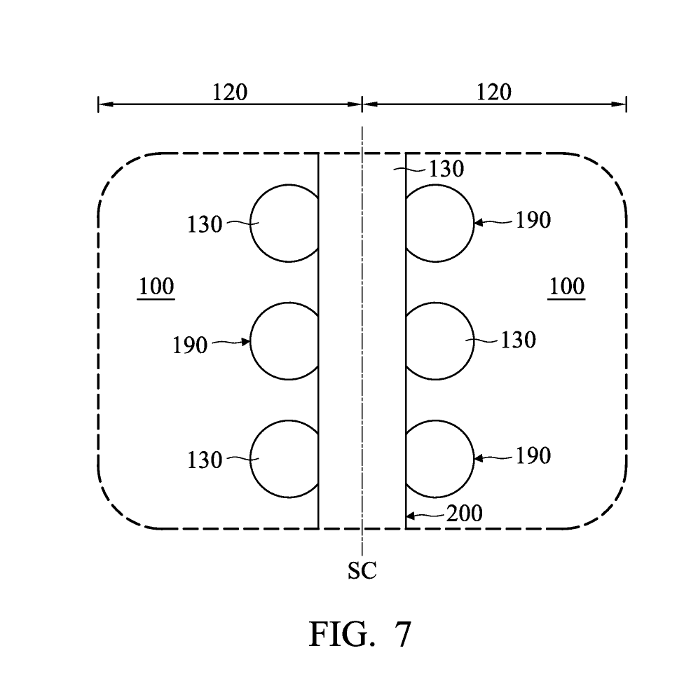

The structure of the photosensitive module 600 shown in FIG. 4G is similar to that of the photosensitive module 300 shown in FIG. 1G. The difference therebetween is that the first openings 190 and the second opening 200 in the photosensitive module 300 are spaced apart and completely isolated from each other through a portion of the substrate 100 (such as a sidewall portion). In contrast, the first openings 190 and the second opening 200 in the photosensitive module 600 are in communication with each other (also referring to FIG. 7, wherein FIG. 7 is a top view of the partial substrate 100). As a result, the substrate 100 has a sidewall portion that is lower than the second surface 100b. In other words, the thickness of the sidewall portion is less than the thickness of the substrate 100. Moreover, an end 220a of the redistribution layer 220 in the photosensitive module 600 extends to the sidewall of the first opening 190, rather than extending on the second surface 100b of the substrate 100. For example, the end 220a of the redistribution layer 220 is located within the hole 240. In the embodiment, the sidewalls of the first opening 190 and the second opening 200 are inclined to the first surface 100a of the substrate 100.

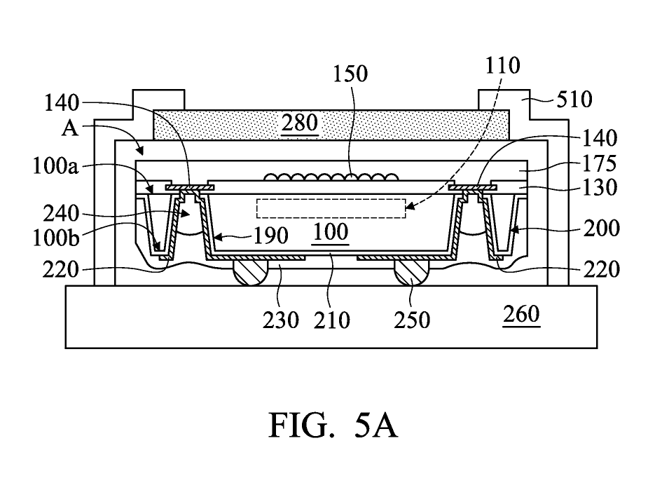

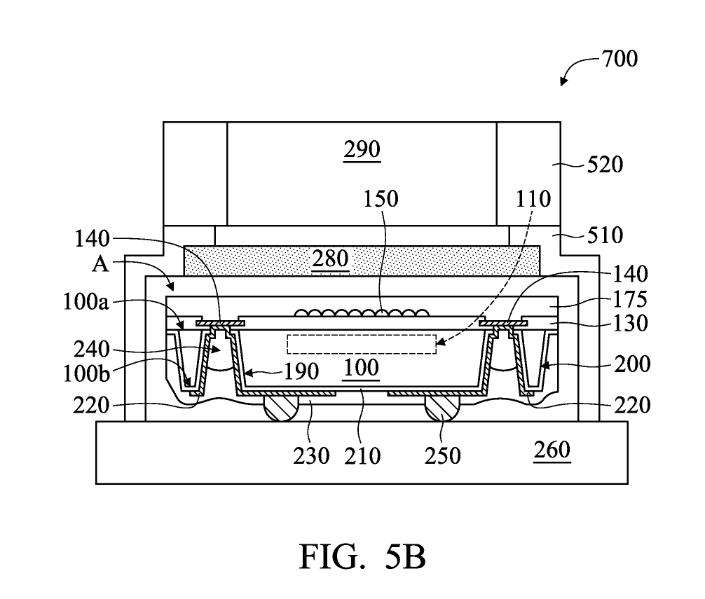

The structure of the photosensitive module 700 shown in FIG. 5B is similar to that of the photosensitive module 300 shown in FIG. 1G. The difference therebetween is that the photosensitive module 300 is a fixed-focus device while the photosensitive module 700 is a zoom (variable focus) device. For example, the optical component in the photosensitive module 700 comprises underlying bracket 510 and filter 280 and overlying actuator 520 and lens 290. The bracket 510 has a capacity space, such that the filter 280 is disposed within the capacity space of the bracket 510 and is fixed to the bracket 510. The capacity space of the bracket 510 can further accommodate the sensing device A on the circuit board 260. As a result, the filter 280 is located between the lens 290 and the sensing device A so as to filter out infrared irradiation. In the embodiment, the actuator 520 may comprise a voice coil motor, an ultrasonic motor, a stepping motor or another suitable actuator. The lens 290 is actuated to move along a direction away from or closer to the sensing device A, so that the photosensitive module 700 has automatic zoom functions. To simplify the diagram, only a flat filter 280, a flat lens 290 and a flat actuator 520 are depicted herein. The structure of the optical component is determined by design requirements and is not limited thereto.

It should be noted that the embodiment of FIG. 5B can be implemented to the embodiments of FIGS. 2D, 3D and 4G. For example, in one embodiment, the photosensitive module 600 may comprise a similar optical component to that in the photosensitive module 700. As a result, the photosensitive module 600 with a sensing device C becomes a zoom device.

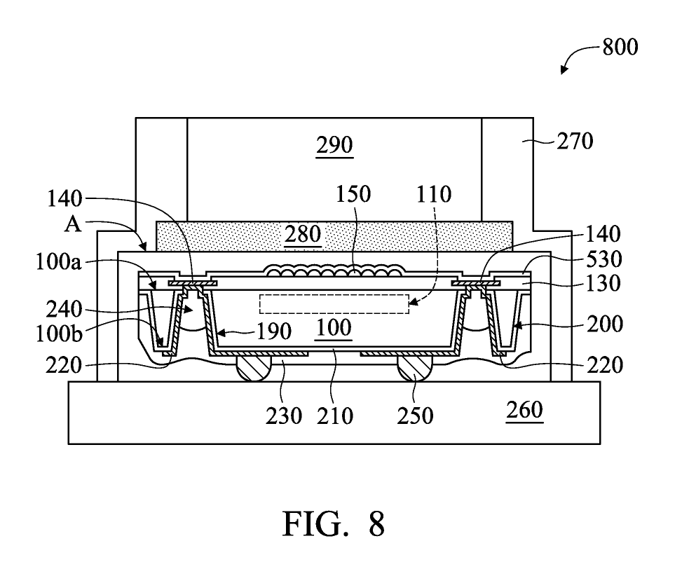

The structure of the photosensitive module 800 shown in FIG. 8 is similar to that of the photosensitive module 300 shown in FIG. 1G. The difference therebetween is that the photosensitive module 300 comprises the anti-contamination layer 175 while the photosensitive module 800 comprises an optical layer 530. In the embodiment, the optical layer 530 may be considered as an anti-contamination layer. The optical layer 530 is conformally disposed on the first surface 100a of the substrate 100, and covers the exposed conducting pads 140 and the exposed optical element 150. As a result, the optical element 150 and the optical layer 530 covering the optical element 150 have the same or similar surface profile. In one embodiment, the optical element 150 is a microlens array, and therefore the surface of the optical layer 530 is partially uneven and comprises multiple projections. In one embodiment, the insulating layer 130 comprises openings exposing the conducting pads 140, and therefore the surface of the optical layer 530 is partially uneven and comprises recessed portions corresponding to the openings.

In one embodiment, the optical layer 530 is made of an anti-reflective material, so that the optical layer 530 can provide the optical element 150 with a function of concentrating light. Therefore, the optical characteristics of the photosensitive module 800 are enhanced. In one embodiment, the optical layer 530 is made of a material with high hardness (such as the hardness is 9H). The hardness of the optical layer 530 may be substantially the same as the hardness of glass. Furthermore, the optical layer 530 has a high surface density, so that contaminants on the optical layer 530 can be removed easily. As a result, the optical element 150, the sensing or device region 110, and the conducting pads 140 can be prevented from being contaminated by the external environment. In some embodiments, the optical layer 530 not only facilitates concentrating light but also functions as an anti-contamination layer.

In one embodiment, the thickness of the optical layer 530 is in a range from about 200 nm to about 500 nm. In one embodiment, the optical layer 530 may be formed by a deposition process (such as a vacuum evaporation process, a coating process, a physical vapor deposition process or another suitable process).

It should be noted that the embodiment of FIG. 8 can also be implemented to the embodiments of FIGS. 2D, 3D, 4G and 5B. For example, in one embodiment, the anti-contamination layer 175 in the photosensitive modules 400, 500, 600 and 700 can be replaced by the optical layer 530. Therefore, the optical characteristics of the photosensitive modules 400, 500, 600 and 700 are further enhanced.

Embodiments of the invention replace a conventional die by a chip package to serve as a sensing device in a photosensitive module. In the aforementioned embodiments, the photosensitive modules 400, 500, 600, 700 and 800 comprise a front-side illumination (FSI) sensing device. However, in other embodiments, the photosensitive modules 400, 500, 600, 700 and 800 may comprise a back-side illumination (BSI) sensing device.

An exemplary embodiment of a method for forming a photosensitive module according to the invention is illustrated in FIGS. 1A to 1G, in which FIGS. 1A to 1G are cross-sectional views of an exemplary embodiment of a method for forming a photosensitive module 300 according to the invention.

Referring to FIG. 1A, a substrate 100 is provided. The substrate 100 has a first surface 100a and a second surface 100b opposite thereto, and comprises a plurality of chip regions 120. To simplify the diagram, only a complete chip region and a partial chip region adjacent thereto are depicted herein. In one embodiment, the substrate 100 may be a silicon substrate or another semiconductor substrate. In another embodiment, the substrate 100 may be a silicon wafer so as to facilitate the wafer-level packaging process.

There is an insulating layer 130 on the first surface 100a of the substrate 100. In general, the insulating layer 130 may be made of an ILD layer, IMD layers and a covering passivation layer. To simplify the diagram, only a single insulating layer 130 is depicted herein. In the embodiment, the insulating layer 130 may comprise an inorganic material, such as silicon oxide, silicon nitride, silicon oxynitride, metal oxide, a combination thereof, or another suitable insulating material.

In the embodiment, one or more conducting pads 140 are located in the insulating layer 130 in each of the chip regions 120. In one embodiment, the conducting pads 140 may be a single conducting layer or comprise multiple conducting layers. To simplify the diagram, only two conducting pads 140 comprising a single conducting layer in the insulating layer 130 are depicted herein as an example. In the embodiment, the insulating layer 130 in each of the chip regions 120 comprises one or more openings exposing the corresponding conducting pads 140 so as to perform a pre-test through the exposed conducting pads 140.

In the embodiment, a sensing or device region 110 is located in each of the chip regions 120. The sensing or device region 110 may be adjacent to the first surface 100a of the substrate 100, and may be electrically connected to the conducting pads 140 through interconnection structures (not shown). Moreover, the sensing or device region 110 may comprise an image sensing element. In the embodiment, the substrate 100 may be fabricated by sequentially performing a front-end process and a back-end process of a semiconductor device. For example, a transistor is formed in the substrate 100 in the sensing or device region 110 during the front-end process. The insulating layer 130, the interconnection structures, and the conducting pads 140 are formed on the substrate 100 in the sensing or device region 110 during the back-end process. In other words, the following method for forming a chip package or a sensing device proceeds subsequently packaging processes to the substrate after the back-end process is finished.

In the embodiment, each of the chip regions 120 comprises an optical element 150 disposed on the first surface 100a of the substrate 100 and corresponding to the sensing or device region 110. In the embodiment, the optical element 150 may be a micro-lens array or another suitable optical element used for an image sensing device.

Next, a cover plate 170 is bonded to the substrate 100 by a temporary adhesive layer 165 (such as a removable tape). The cover plate 170 is used to provide support and protection. In one embodiment, the cover plate 170 may comprise glass or another suitable substrate material. The temporary adhesive layer 165 formed between the cover plate 170 and the substrate 100 completely covers the first surface 100a of the substrate 100. For example, the temporary adhesive layer 165 covers the conducting pads 140, the sensing or device region 110, and the optical element 150.

In other embodiments, a spacer layer (not shown) may be formed on the insulating layer 130 by a deposition process. A surfactant layer (not shown) may optionally be added between the spacer layer and the insulating layer 130 and between the spacer layer and the substrate 100. The surfactant layer comprises a suitable material facilitating subsequent separation of the spacer layer from the insulating layer 130 and the substrate 100. The spacer layer and the surfactant layer cover the conducting pads 140 but expose the sensing or device region 110 and the optical element 150. Next, the substrate 100 is bonded to the cover plate 170. The spacer layer forms a cavity between the substrate 100 and the cover plate 170 in each chip region 120. As a result, the optical element 150 is located in the cavity and the optical element 150 in the cavity is protected by the cover plate 170.

Referring to FIG. 1B, a thinning process (such as an etching process, a milling process, a grinding process or a polishing process) using the cover plate 170 as a carrier substrate is performed on the second surface 100b of the substrate 100. As a result, the thickness of the substrate 100 is reduced (such as less than about 100 μm).

Next, a plurality of first openings 190 and a second opening 200 may be simultaneously formed in the substrate 100 in each chip region 120 by a lithography process and an etching process (such as a dry etching process, a wet etching process, a plasma etching process, a reactive ion etching process, or another suitable process). The first openings 190 and the second opening 200 expose the insulating layer 130 from the second surface 100b of the substrate 100. In other embodiments, the first openings 190 and the second opening 200 may be respectively formed by a notching process, and lithography and etching processes. In the embodiment, the first openings 190 correspond to the conducting pads 140 and penetrate the substrate 100. The diameter of the first openings 190 adjacent to the first surface 100a is less than that of the first openings 190 adjacent to the second surface 100b. Therefore, the difficulty of the process for subsequently forming layers in the first openings 190 is reduced, and reliability is improved. For example, since the diameter of the first openings 190 adjacent to the first surface 100a is less than that of the first openings 190 adjacent to the second surface 100b, layers (such as an insulating layer 210 and a redistribution layer 220) subsequently formed in the first openings 190 can be easily deposited on a corner between the first openings 190 and the insulating layer 130. As a result, affecting electrical connection paths and inducing leakage current problems are avoidable.

The second opening 200 extends along scribed lines SC between the adjacent chip regions 120 and penetrates the substrate 100. Therefore, portions of the substrate 100 in the chip regions 120 are separated from each other. As shown in FIG. 6, multiple first openings 190 in two adjacent chip regions 120 are arranged apart along the second opening 200. The first openings 190 and the second opening 200 are separated from each other by a portion of the substrate 100 (such as a sidewall portion). In other embodiments, a portion of the first openings 190 adjacent to the second surface 100b and a portion of the second opening 200 adjacent to the second surface 100b may be in communication with each other. As a result, the substrate 100 has a sidewall portion that is lower than the second surface 100b.

In one embodiment, the second opening 200 extends along the chip regions 120 and surrounds the first openings 190. In the embodiment, the top-view profile of the first openings 190 is different from that of the second opening 200. For example, the top-view profile of the first openings 190 is circular while the top-view profile of the second opening 200 is rectangular, as shown in FIG. 6. It should be noted that the top-view profiles of the first openings 190 and the second opening 200 may be another shape, and they are not limited thereto.

Referring to FIG. 1C, an insulating layer 210 may be formed on the second surface 100b of the substrate 100 by a deposition process (such as a coating process, a physical vapor deposition process, a chemical vapor deposition process or another suitable process). The insulating layer 210 conformally deposited on the sidewalls and the bottoms of the first openings 190 and the second opening 200. In the embodiment, the insulating layer 210 may comprise epoxy resin, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates) or another suitable insulating material.

Next, the insulating layer 210 on the bottom of the first openings 190 and the underlying insulating layer 130 are removed by lithography and etching processes, such that the first openings 190 extend into the insulating layer 130 and expose the corresponding conducting pads 140.

A patterned redistribution layer 220 is formed on the insulating layer 210 by a deposition process (such as a coating process, a physical vapor deposition process, a chemical vapor deposition process, an electroplating process, an electroless plating process or another suitable process) and lithography and etching processes. The redistribution layer 220 conformally extends to the sidewalls and the bottoms of the first openings 190 without extending into the second opening 200. The redistribution layer 220 extends on the second surface 100b between the first openings 190 and the second opening 200. The redistribution layer 220 is electrically isolated from the substrate 100 by the insulating layer 210. The redistribution layer 220 may be in direct electrical contact with or indirectly electrically connected to the exposed conducting pads 140 through the first openings 190. As a result, the redistribution layer 220 in the first openings 190 is also referred to as a through silicon via. In one embodiment, the redistribution layer 220 may comprise aluminum, copper, gold, platinum, nickel, tin, a combination thereof, a conductive polymer material, a conductive ceramic material (such as indium tin oxide or indium zinc oxide), or another suitable conductive material.

Referring to FIG. 1D, a protection layer 230 may be formed on the second surface 100b of the substrate 100 by a deposition process. The protection layer 230 fills the first openings 190 and the second opening 200 to cover the redistribution layer 220. In one embodiment, the protection layer 230 may comprise epoxy resin, solder mask, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates), or another suitable insulating material.

In the embodiment, the first openings 190 are not fully filled with the protection layer 230, so that a hole 240 is formed between the redistribution layer 220 and the protection layer 230 within the first openings 190. In one embodiment, the interface between the protection layer 230 and the hole 240 has an arcuate contour. In other embodiments, the first openings 190 may be fully filled with the protection layer 230.

Next, openings may be formed in the protection layer 230 on the second surface 100b of the substrate 100 by lithography and etching processes so as to expose portions of the redistribution layer 220. Subsequently, conducting structures 250 (such as solder balls, bumps or conductive pillars) may be filled in the openings of the protection layer 230 by a electroplating process, a screen printing process or another suitable process to electrically connect to the exposed redistribution layer 220. In one embodiment, the conducting structures 250 may comprise tin, lead, copper, gold, nickel, or a combination thereof.

Referring to FIG. 1E, after forming the conducting structures 250, the cover plate 170 and the temporary adhesive layer 165 are removed from the substrate 100 to expose the conducting pads 140 and the optical element 150. Next, an anti-contamination layer 175 may be formed on the first surface 100a of the substrate 100 by a deposition process. The anti-contamination layer 175 covers and is in direct contact with the exposed conducting pads 140 and the exposed optical element 150. In one embodiment, the anti-contamination layer 175 may completely cover the first surface 100a of the substrate 100. In the embodiment, the anti-contamination layer 175 is made of a light-transmissive insulating material (such as a polymer material). In one embodiment, the thickness of the anti-contamination layer 175 may be in a range from about 50 μm to about 200 μm.

After removing the cover plate 170 and forming the anti-contamination layer 175, the protection layer 230 and the anti-contamination layer 175 are diced along the scribed lines SC (equivalent to along the second opening 200), and thereby forming a plurality of separated chip packages (i.e., sensing devices A). For example, a laser cutting process can be performed in order to avoid displacement of upper and lower layers.

Next, referring to FIG. 1F, the sensing device A with the anti-contamination layer 175 is bonded onto a circuit board 260. The sensing device A is electrically connected to the circuit board 260 through the conducting structures 250 on the second surface 100b of the substrate 100. For example, the conducting structures 250 may be formed of solder. After the sensing device A is placed on the circuit board 260, a reflow process may be performed to bond the sensing device A to the circuit board 260 through solder balls. Furthermore, before or after the sensing device A is bonded onto the circuit board 260, the required passive elements (such as inductors, capacitors, resistors or other electronic elements) may be formed on the circuit board 260 by surface mount technology (SMT). In addition, the sensing device A and the aforementioned passive elements may be simultaneously bonded onto the circuit board 260 by the same reflow process.

In the embodiment, there is an anti-contamination layer 175 on the first surface 100a of the substrate 100, so the sensing device A (especially the sensing or device region 110 and the optical element 150) can be prevented from being contaminated during the reflow process by the anti-contamination layer 175. Therefore, the quality of the photosensitive module is enhanced.

Referring to FIG. 1G, after bonding the sensing device A to the circuit board 260, an optical component is provided on the circuit board 260. The optical component comprises a holder 270, a filter 280 and a lens 290. The holder 270 has a capacity space, so that the filter 280 and the lens 290 are disposed within the capacity space of the holder 270 and are fixed to the holder 270. Next, the optical component corresponds to the sensing device A and is mounted onto the circuit board 260. As a result, the sensing device A on the circuit board 260 is also accommodated in the capacity space of the holder 270. The filter 280 is located between the lens 290 and the first surface 100a of the substrate 100. Therefore, the photosensitive module 300 is fabricated. In the embodiment, the circuit board 260 may be a panelized PCB or a de-panel board. When the circuit board 260 is a panelized PCB, the circuit board 260 can optionally be cut into de-panel boards after mounting the optical component on the circuit board 260.

In the embodiment, the filter 280 needs to be spaced apart from the sensing or device region 110 by an appropriate distance, so the photosensitive module can provide good image quality. In one embodiment, the filter 280 is formed of a light-transmissive material (such as glass) and a filter layer thereon. Furthermore, the lens 290 can be formed of a single lens set or comprise multiple lens sets. To simplify the diagram, only a flat filter 280 and a flat lens 290 are depicted herein. The structure of the optical component is determined by design requirements and is not limited thereto.

Another exemplary embodiment of a method for forming a photosensitive module according to the invention is illustrated in FIGS. 2A to 2D, in which FIGS. 2A to 2D are cross-sectional views of another exemplary embodiment of a method for forming a photosensitive module 400 according to the invention. Elements in FIGS. 2A to 2D that are the same as those in FIGS. 1A to 1G are labeled with the same reference numbers as in FIGS. 1A to 1G and are not described again for brevity.

Referring to FIG. 2A, the cover plate 170 may be bonded to the substrate 100 through the temporary adhesive layer 165 by a step that is the same as or similar to the step shown in FIG. 1A. However, in other embodiments, the cover plate 170 may be bonded to the substrate 100 through a spacer layer (not shown), and the spacer layer forms a cavity between the substrate 100 and the cover plate 170 in each chip region 120 such that the optical element 150 is located in the cavity. A surfactant layer (not shown) may optionally be added between the spacer layer and the substrate 100. The surfactant layer comprises a suitable material facilitating subsequent separation of the spacer layer from the substrate 100.

Next, the substrate 100 is thinned, and the first openings 190 and the second opening 200 are formed in the substrate 100 by steps that is the same as or similar to the step shown in FIG. 1B. In the embodiment, the first openings 190 and the second opening 200 are spaced apart and completely isolated from each other through a portion of the substrate 100. In other embodiments, a portion of the first openings 190 adjacent to the second surface 100b and a portion of the second opening 200 adjacent to the second surface 100b may be in communication with each other. As a result, the substrate 100 has a sidewall portion that is lower than the second surface 100b. Subsequently, the insulating layer 210 and the redistribution layer 220 are formed on the second surface 100b of the substrate 100 by steps that are the same as or similar to the steps shown in FIG. 1C.

Next, referring to FIG. 2B, after forming the redistribution layer 220, the cover plate 170 and the temporary adhesive layer 165 are removed from the substrate 100 to expose the conducting pads 140 and the optical element 150. In other embodiments, when the cover plate 170 is bonded to the substrate 100 through a spacer layer, the cover plate 170 and the spacer layer are removed together after forming the redistribution layer 220. Since there is a surfactant layer between the spacer layer and the substrate 100, it is easier for the spacer layer to be completely removed without remaining on the substrate 100.

Next, the anti-contamination layer 175 may be formed on the first surface 100a of the substrate 100 by a deposition process. The anti-contamination layer 175 covers the exposed conducting pads 140 and the exposed optical element 150. In one embodiment, the anti-contamination layer 175 may completely cover the first surface 100a of the substrate 100.

After removing the cover plate 170 and forming the anti-contamination layer 175, the anti-contamination layer 175 are diced along the scribed lines SC (equivalent to along the second opening 200), and thereby forming a plurality of separated chip packages (i.e., sensing devices B). In the embodiment, there is no protection layer on the second surface 100b of the substrate 100 in the sensing devices B. Therefore, the redistribution layer 220 is completely exposed.

Next, referring to FIG. 2C, the sensing device B with the anti-contamination layer 175 is bonded onto the circuit board 260. The sensing device B is electrically connected to the circuit board 260 through a plurality of conducting structures 250 between the redistribution layer 220 and the circuit board 260. In one embodiment, the conducting structures 250 may be formed by dipping flow (dipping flow) technology. For example, the conducting structures made of solder may be previously formed on the circuit board 260. A reflow process is then performed to electrically connect the sensing device B and the circuit board 260 through solder bumps or bonding pads. Furthermore, before bonding the sensing device B onto the circuit board 260, the required passive elements (such as inductors, capacitors, resistors or other electronic elements) may be formed on the circuit board 260 by surface mount technology. In addition, the sensing device B and the aforementioned passive elements may be simultaneously bonded onto the circuit board 260 by the same reflow process. In the embodiment, there is an anti-contamination layer 175 on the first surface 100a of the substrate 100, so the sensing device B (especially the sensing or device region 110 and the optical element 150) can be prevented from being contaminated during the dipping flow or reflow process by the anti-contamination layer 175. Therefore, the quality of the photosensitive module is enhanced.

In other embodiments, the conducting structures 250 may be conductive glue or another conductive adhesive material so as to attach the sensing device B onto the circuit board 260 and form electrical connection paths through the conducting structures 250. Furthermore, the required passive elements can be previously formed on the circuit board 260 by surface mount technology before bonding the sensing device B onto the circuit board 260 so as to prevent the sensing device B from being contaminated.

Referring to FIG. 2D, after bonding the sensing device B to the circuit board 260, the optical component comprising the holder 270, the filter 280 and the lens 290 may be provided on the circuit board 260 by steps that are the same as or similar to the steps shown in FIGS. 1F to 1G. The optical component corresponds to the sensing device B and is mounted onto the circuit board 260. As a result, the sensing device B on the circuit board 260 is accommodated in the capacity space of the holder 270. Therefore, the photosensitive module 400 is fabricated.

Yet another exemplary embodiment of a method for forming a photosensitive module according to the invention is illustrated in FIGS. 3A to 3D, in which FIGS. 3A to 3D are cross-sectional views of yet another exemplary embodiment of a method for forming a photosensitive module 500 according to the invention. Elements in FIGS. 3A to 3D that are the same as those in FIGS. 1A to 1G are labeled with the same reference numbers as in FIGS. 1A to 1G and are not described again for brevity.

Referring to FIG. 3A, the cover plate 170 may be bonded to the substrate 100 through the temporary adhesive layer 165 by a step that is the same as or similar to the step shown in FIG. 1A. However, in other embodiments, the cover plate 170 may be bonded to the substrate 100 through a spacer layer (not shown), and the spacer layer forms a cavity between the substrate 100 and the cover plate 170 in each chip region 120 such that the optical element 150 is located in the cavity. A surfactant layer (not shown) may optionally be added between the spacer layer and the substrate 100. The surfactant layer comprises a suitable material facilitating subsequent separation of the spacer layer from the substrate 100.

Next, the substrate 100 is thinned, and the first openings 190 and the second opening 200 are formed in the substrate 100 by steps that is the same as or similar to the step shown in FIG. 1B. In the embodiment, the first openings 190 and the second opening 200 are spaced apart and completely isolated from each other through a portion of the substrate 100. In other embodiments, a portion of the first openings 190 adjacent to the second surface 100b and a portion of the second opening 200 adjacent to the second surface 100b may be in communication with each other. As a result, the substrate 100 has a sidewall portion that is lower than the second surface 100b. Subsequently, the insulating layer 210 and the redistribution layer 220 are formed on the second surface 100b of the substrate 100 by steps that are the same as or similar to the steps shown in FIG. 1C.

Next, referring to FIG. 3B, after forming the redistribution layer 220, the cover plate 170 and the temporary adhesive layer 165 are removed from the substrate 100 to expose the conducting pads 140 and the optical element 150. In other embodiments, when the cover plate 170 is bonded to the substrate 100 through a spacer layer, the cover plate 170 and the spacer layer are removed together after forming the redistribution layer 220. Since there is a surfactant layer between the spacer layer and the substrate 100, it makes it easier for the spacer layer to be completely removed without remaining on the substrate 100.

After removing the cover plate 170, a dicing process is performed along the scribed lines SC (equivalent to along the second opening 200), and thereby forming a plurality of separated chip packages (i.e., sensing devices B). In the embodiment, there is no protection layer on the second surface 100b of the substrate 100 in the sensing devices B. Therefore, the redistribution layer 220 is completely exposed. In the embodiment, there is no anti-contamination layer on the first surface 100a of the substrate 100 in the sensing devices B. Therefore, the conducting pads 140 are exposed.

Next, referring to FIG. 3C, the sensing device B is bonded onto the circuit board 260. The sensing device B is electrically connected to the circuit board 260 through a plurality of conducting structures 250 between the redistribution layer 220 and the circuit board 260. In one embodiment, the conducting structures 250 may be formed by dipping flow technology. In other embodiments, the conducting structures 250 may be conductive glue or another conductive adhesive material so as to attach the sensing device B onto the circuit board 260 and form electrical connection paths through the conducting structures 250. Since there is no need to use dipping flow technology or perform a reflow process to form the conducting structures 250, the sensing device B can be prevented from being contaminated. Furthermore, before bonding the sensing device B onto the circuit board 260, the required passive elements can be previously formed on the circuit board 260 by surface mount technology. As a result, the sensing device B can be prevented from being contaminated during the reflow process, and thereby improving the quality of the photosensitive module. Moreover, there is no need to additionally form a protection layer or an anti-contamination layer, so the fabricating steps are simplified and the fabrication cost is reduced.

Referring to FIG. 3D, after bonding the sensing device B to the circuit board 260, the optical component comprising the holder 270, the filter 280 and the lens 290 may be provided on the circuit board 260 by steps that are the same as or similar to the steps shown in FIGS. 1F to 1G. Therefore, the photosensitive module 500 is fabricated.

Yet another exemplary embodiment of a method for forming a photosensitive module according to the invention is illustrated in FIGS. 4A to 4G, in which FIGS. 4A to 4G are cross-sectional views of yet another exemplary embodiment of a method for forming a photosensitive module 600 according to the invention. Elements in FIGS. 4A to 4G that are the same as those in FIGS. 1A to 1G are labeled with the same reference numbers as in FIGS. 1A to 1G and are not described again for brevity.

Referring to FIG. 4A, a substrate 100 may be provided by steps that are the same as or similar to the steps shown in FIG. 1A. Next, a spacer layer 160 may be formed on the insulating layer 130 by a deposition process (such as a coating process, a physical vapor deposition process, a chemical vapor deposition process or another suitable process). A surfactant layer (not shown) may optionally be added between the spacer layer 160 and the insulating layer 130 and between the spacer layer 160 and the substrate 100. The surfactant layer comprises a suitable material facilitating subsequent separation of the spacer layer 160 from the insulating layer 130 and the substrate 100.

The spacer layer 160 covers the conducting pads 140, and exposes the sensing or device region 110 and the optical element 150. In one embodiment, the spacer layer 160 does not substantially absorb moisture. In one embodiment, the spacer layer 160 may be adhesive and may contact none of the adhesive glue, thereby assuring that the spacer layer 160 will not move due to the disposition of the adhesive glue. Furthermore, since the adhesive glue is not needed, the sensing device can be prevented from being contaminated by the overflow of the adhesive glue. In the embodiment, the spacer layer 160 may comprise epoxy resin, inorganic materials (such as silicon oxide, silicon nitride, silicon oxynitride, metal oxide or a combination thereof), organic polymer materials (such as polyimide, butylcyclobutene, parylene, polynaphthalenes, fluorocarbons or acrylates) or another suitable insulating material. In another embodiment, the spacer layer 160 may comprise a photoresist material, and may be patterned by exposure and developing processes to expose the sensing or device region 110 and the optical element 150.

Next, the substrate 100 is bonded to a cover plate 170, and the spacer layer 160 forms a cavity 180 between the substrate 100 and the cover plate 170 in each chip region 120. As a result, the optical element 150 is located in the cavity 180, and the optical element 150 in the cavity 180 is protected by the cover plate 170.

In another embodiment, the spacer layer 160 and the surfactant layer may be previously formed on the cover plate 170. The substrate 100 is then bonded to the cover plate 170 through the spacer layer 160 and the surfactant layer on the cover plate 170. In other embodiments, the cover plate 170 may be bonded to the substrate 100 by a temporary adhesive layer (such as a removable tape) without forming the described spacer layer 160.

Referring to FIG. 4B, a thinning process (such as an etching process, a milling process, a grinding process or a polishing process) using the cover plate 170 as a carrier substrate is performed on the second surface 100b of the substrate 100 to reduce the thickness of the substrate 100.

Next, a plurality of first openings 190 and a second opening 200 may be simultaneously formed in the substrate 100 in each chip region 120 by a lithography process and an etching process (such as a dry etching process, a wet etching process, a plasma etching process, a reactive ion etching process, or another suitable process). The first openings 190 and the second opening 200 expose the insulating layer 130 from the second surface 100b of the substrate 100. In other embodiments, the first openings 190 and the second opening 200 may be respectively formed by a notching process, and lithography and etching processes.

In the embodiment, the first openings 190 correspond to the conducting pads 140 and penetrate the substrate 100. The diameter of the first openings 190 adjacent to the first surface 100a is less than that of the first openings 190 adjacent to the second surface 100b. Therefore, the difficulty of the process for subsequently forming layers in the first openings 190 is reduced, and reliability is improved. Moreover, the second opening 200 extends along the scribed lines SC between the adjacent chip regions 120 and penetrates the substrate 100, such that the substrate 100 in each of the chip regions 120 is separated from each other. As shown in FIG. 7, multiple first openings 190 in two adjacent chip regions 120 are arranged apart along the second opening 200. A portion of the first openings 190 adjacent to the second surface 100b and a portion of the second opening 200 adjacent to the second surface 100b are in communication with each other. Therefore, the substrate 100 has a sidewall portion that is lower than the second surface 100b. In other words, the thickness of the sidewall portion is less than the thickness of the substrate 100. In one embodiment, the second opening 200 may extend along the chip regions 120 and surround the first openings 190.

In the embodiment, since the first openings 190 and the second opening 200 are in communication with each other, rather than being completely isolated by a portion of the substrate 100, it is possible to avoid the buildup of stress in the substrate 100 between the first openings 190 and the second opening 200. Stress can be mitigated and released through the second opening 200, and thereby preventing the sidewall portions of the substrate 100 being cracked.

Referring to FIG. 4C, an insulating layer 210 may be formed on the second surface 100b of the substrate 100 by a deposition process (such as a coating process, a physical vapor deposition process, a chemical vapor deposition process or another suitable process). The insulating layer 210 conformally deposited on the sidewalls and the bottoms of the first openings 190 and the second opening 200. Next, the insulating layer 210 on the bottom of the first openings 190 and the underlying insulating layer 130 are removed by lithography and etching processes, such that the first openings 190 extend into the insulating layer 130 and expose the corresponding conducting pads 140.

A patterned redistribution layer 220 is formed on the insulating layer 210 by a deposition process (such as a coating process, a physical vapor deposition process, a chemical vapor deposition process, an electroplating process, an electroless plating process or another suitable process) and lithography and etching processes. The redistribution layer 220 conformally extends to the sidewalls and the bottoms of the first openings 190 without extending into the second opening 200. Moreover, since the first openings 190 and the second opening 200 are in communication with each other, an end 220a of the redistribution layer 220 extends to the sidewall of the first opening 190, rather than extending on the second surface 100b of the substrate 100.

Referring to FIG. 4D, a protection layer 230 may be formed on the second surface 100b of the substrate 100 by a deposition process, and fill the first openings 190 and the second opening 200 to cover the redistribution layer 220. In the embodiment, the first openings 190 are not fully filled with the protection layer 230, so that a hole 240 is formed between the redistribution layer 220 and the protection layer 230 within the first openings 190. For example, the end 220a of the redistribution layer 220 is located within the hole 240 in the first opening 190. In one embodiment, the interface between the protection layer 230 and the hole 240 has an arcuate contour. In other embodiments, the first openings 190 may be fully filled with the protection layer 230.

Next, openings may be formed in the protection layer 230 on the second surface 100b of the substrate 100 by lithography and etching processes so as to expose portions of the redistribution layer 220. Subsequently, conducting structures 250 (such as solder balls, bumps or conductive pillars) may be filled in the openings of the protection layer 230 by a electroplating process, a screen printing process or another suitable process to electrically connect to the exposed redistribution layer 220.

Referring to FIG. 4E, after forming the conducting structures 250, the cover plate 170 is removed from the substrate 100 to expose the conducting pads 140 and the optical element 150. In the embodiment, since there is a surfactant layer between the spacer layer 160 and the insulating layer 130 and between the spacer layer 160 and the substrate 100, the spacer layer 160 can be separated from the insulating layer 130 and the substrate 100 when the cover plate 170 is removed. It is facilitated that the spacer layer 160 is completely removed without remaining on the insulating layer 130 and the substrate 100.

Next, an anti-contamination layer 175 may be formed on the first surface 100a of the substrate 100 by a deposition process. The anti-contamination layer 175 covers the exposed conducting pads 140 and the exposed optical element 150. In one embodiment, the anti-contamination layer 175 may completely cover the first surface 100a of the substrate 100. In the embodiment, the anti-contamination layer 175 is made of a light-transmissive insulating material (such as a polymer material). In one embodiment, the thickness of the anti-contamination layer 175 may be in a range from about 50 μm to about 200 μm.

After removing the cover plate 170 and forming the anti-contamination layer 175, a dicing process is performed along the scribed lines SC (equivalent to along the second opening 200), and thereby forming a plurality of separated chip packages (i.e., sensing devices C). For example, a laser cutting process can be performed in order to avoid displacement of upper and lower layers.

Next, referring to FIG. 4F, the sensing device C is bonded onto a circuit board 260, and is electrically connected to the circuit board 260 through the conducting structures 250 on the second surface 100b of the substrate 100. For example, the conducting structures 250 may be formed of solder. After the sensing device C is placed on the circuit board 260, a reflow process may be performed to bond the sensing device C to the circuit board 260 through solder balls. Furthermore, before or after the sensing device C is bonded onto the circuit board 260, the required passive elements may be formed on the circuit board 260 by surface mount technology. In addition, the sensing device C and the aforementioned passive elements may be simultaneously bonded onto the circuit board 260 by the same reflow process.

In the embodiment, there is an anti-contamination layer 175 on the first surface 100a of the substrate 100, so the sensing device C (especially the sensing or device region 110 and the optical element 150) can be prevented from being contaminated during the reflow process by the anti-contamination layer 175. Therefore, the quality of the photosensitive module is enhanced.

Referring to FIG. 4G, after bonding the sensing device C to the circuit board 260, an optical component comprising a holder 270, a filter 280 and a lens 290 is provided on the circuit board 260. The optical component corresponds to the sensing device C and is mounted onto the circuit board 260. As a result, the sensing device C on the circuit board 260 is accommodated in the capacity space of the holder 270. Therefore, the photosensitive module 600 is fabricated.

Yet another exemplary embodiment of a method for forming a photosensitive module according to the invention is illustrated in FIGS. 5A to 5B, in which FIGS. 5A to 5B are cross-sectional views of yet another exemplary embodiment of a method for forming a photosensitive module 700 according to the invention. Elements in FIGS. 5A to 5B that are the same as those in FIGS. 1A to 1G are labeled with the same reference numbers as in FIGS. 1A to 1G and are not described again for brevity.

Referring to FIG. 5A, a sensing device A, which comprises an anti-contamination layer 175 on a first surface 100a of a substrate 100, may be formed by steps that are the same as or similar to the steps shown in FIGS. 1A to 1E. The sensing device A may be bonded onto a circuit board 260 by steps that are the same as or similar to the steps shown in FIG. 1F.

Next, a bracket 510 having a capacity space is provided. A filter 280 is disposed within the capacity space of the bracket 510 and is fixed to the bracket 510. The bracket 510 is mounted on the circuit board 260. As a result, the sensing device A on the circuit board 260 is also accommodated in the capacity space of the bracket 510, and the filter 280 corresponds to the sensing or device region 110 and the optical element 150.

Next, an actuator 520 and a lens 290 disposed therein are provided. In the embodiment, the actuator 520 may comprise a voice coil motor, an ultrasonic motor, a stepping motor or another suitable actuator so as to provide automatic zoom functions. Subsequently, the actuator 520 and the lens 290 are mounted on the bracket 510 on the circuit board 260. The lens 290 corresponds to the sensing or device region 110 and the optical element 150. As a result, the filter 280 is located between the lens 290 and the sensing device A. Therefore, the photosensitive module 700 is fabricated.

In the embodiment, after mounting the bracket 510 and the filter 280 on the circuit board 260 and before mounting the actuator 520 and the lens 290 on the bracket 510, an initial test may be previously performed so as to test the image quality sensed by the sensing device A. The actuator 520 and the lens 290 are subsequently mounted. Accordingly, it helps ensure the reliability of the photosensitive module, and reduce the fabrication cost. In addition, the embodiment of FIGS. 5A to 5B can also be implemented to the embodiments of FIGS. 2A to 2D, FIGS. 3A to 3D, and FIGS. 4A to 4G. For example, the steps shown in FIG. 2D can be replaced by steps that are the same as or similar to the steps shown in FIGS. 5A to 5B. As a result, the photosensitive module 400 with the sensing device B has automatic zoom functions and becomes a zoom device.

It should be noted that although the embodiments of FIGS. 1A to 1G, FIGS. 2A to 2D, FIGS. 3A to 3D, FIGS. 4A to 4G, and FIGS. 5A to 5B provide a method for forming a photosensitive module with a FSI sensing device, the method for forming external electrical connection paths (such as the opening in the substrate, the redistribution layer, the protection layer, or the conducting structures therein) can be implemented to the processes of a BSI sensing device.

According to the aforementioned embodiments, removing the cover plate 170 from the substrate 100 can facilitate reducing the overall height of the sensing device significantly, and increasing the light transmittance of the photosensitive modules. Furthermore, the cover plate 170 is only used as a temporary substrate and does not affect the sensing capability of the photosensitive module. Therefore, there is no need to use high-quality glass material as the cover plate 170 and an opaque substrate material may optionally be used.

In comparison with removing the cover plate 170 after performing the dicing process, removing the cover plate 170 from the substrate 100 before performing the dicing process (i.e., during wafer-level processes) can help simplify the fabrication steps. Moreover, the difficulty of the process for removing the cover plate 170 can be reduced.

In general, it is necessary to press a die in order to successfully attach it onto a PCB, using COB technology. Accordingly, the die should have a certain thickness (such as about 250 μm), in order to avoid causing physical damage during attachment.

According to the aforementioned embodiments, the sensing device is placed softly on the circuit board 260 during the process (such as a reflow process) for bonding the sensing device on the circuit board 260. Therefore, the thickness of the substrate in the sensing device can be further reduced without occurring crack or damage problems in the substrate, and thereby facilitating the shrinkage of the overall size of the photosensitive module. Moreover, during the reflow process, the sensing device (especially the sensing or device region 110 and the optical element 150) can be prevented from being contaminated by the anti-contamination layer 175 or the optical or anti-contamination layer 530 on the substrate 100, and thereby improving the quality of the photosensitive module.

In addition, when a sensing device uses solder balls as external conducting structures and is bonded onto a circuit board through the solder balls, a sufficient amount of tin is required to ensure bonding results. Therefore, it is difficult to reduce the height of the conducting structures. According to some embodiments of the invention, the conducting structures 250 (such as solder bumps) can be previously formed on the circuit board 260. The sensing device A is then bonded to the circuit board 260 through the conducting structures 250. As a result, the height of the conducting structures 250 can be reduced, and thereby facilitating the shrinkage of the overall size of the photosensitive module. Furthermore, when the redistribution layer 220 of the sensing device is exposed, the sensing device can be successfully electrically connected to the conducting structures 250 on the circuit board 260 more easily. The conducting structures 250 may be conductive glue or another conductive adhesive material. Therefore, the height of the conducting structures 250 can be reduced even further. There is no need to perform a reflow process, thereby preventing the sensing device from being contaminated.

In the embodiments, the sensing device is electrically connected to the circuit board 260 through the TSVs (i.e., the redistribution layer 220 in the first openings 190) without performing bonding wire processes to form bonding wires. Accordingly, the fabrication cost is significantly lowered. In addition, wafer-level chip scale packaging (CSP) technology is used in the invention to form sensing devices of photosensitive modules. Massive sensing devices can be fabricated, and thereby further reducing the cost and the fabricating time.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a photosensitive module, comprising:
providing a substrate having a first surface and a second surface opposite thereto, wherein a conducting pad is located on the first surface;
providing a cover plate on the first surface of the substrate;
forming a first opening penetrating the substrate and exposing the conducting pad;
forming a redistribution layer in the first opening, wherein the redistribution layer is electrically connected to the conducting pad;
removing the cover plate and subsequently performing a dicing process to form a sensing device;
bonding the sensing device to a circuit board; and
mounting an optical component on the circuit board, wherein the optical element set corresponds to the sensing device.

2. The method as claimed in claim 1, further comprising depositing an anti-contamination layer on the first surface of the substrate and bonding the sensing device with the anti-contamination layer to the circuit board after removing the cover plate and before performing the dicing process.

3. The method as claimed in claim 1, further comprising forming a conducting structure, wherein the conducting structure is electrically connected to the redistribution layer and is located between the redistribution layer and the circuit board.

4. The method as claimed in claim 3, wherein the step of bonding the sensing device to the circuit board comprises performing a reflow process.

5. The method as claimed in claim 3, wherein the conducting structure is formed before bonding the sensing device to the circuit board, and wherein the redistribution layer of the sensing device is exposed.

6. The method as claimed in claim 3, wherein the conducting structure is adhesive, and the method further comprises performing a reflow process before bonding the sensing device to the circuit board.

7. The method as claimed in claim 1, wherein a temporary adhesive layer is formed between the cover plate and the first surface and covers the conducting pads, and wherein the method further comprises removing the temporary adhesive layer before performing the dicing process.

8. The method as claimed in claim 1, wherein a spacer layer is formed between the cover plate and the first surface and covers the conducting pads, and wherein the method further comprises removing the spacer layer before performing the dicing process.

9. The method as claimed in claim 1, further comprising forming a second opening, wherein the dicing process is performed along the second opening.

10. The method as claimed in claim 9, wherein the first opening is in communication with the second opening.

11. The method as claimed in claim 9, wherein a sidewall portion of the substrate is located between the first opening and the second opening, and a thickness of the sidewall portion is less than that of the substrate.

12. The method as claimed in claim 9, further comprising forming a protection layer, wherein the protection layer fills the first opening and the second opening.

13. The method as claimed in claim 1, further comprising forming a protection layer, wherein the protection layer partially fills the first opening so that a hole is formed between the redistribution layer and the protection layer within the first opening.

14. The method as claimed in claim 13, wherein the redistribution layer has an end located within the hole.

15. A photosensitive module, comprising:
a sensing device bonded onto a circuit board, wherein the sensing device comprises:
a substrate having a first surface and a second surface opposite thereto;
a conducting pad disposed on the first surface;
an anti-contamination layer disposed on the first surface of the substrate and covering the conducting pad;
a first opening penetrating the substrate and exposing the conducting pad; and
a redistribution layer disposed in the first opening to electrically connect to the conducting pad; and
an optical component corresponding to the sensing device and mounted on the circuit board.

16. The photosensitive module as claimed in claim 15, wherein the sensing device further comprises a conducting structure, wherein the conducting structure is electrically connected to the redistribution layer and is located between the redistribution layer and the circuit board.

17. The photosensitive module as claimed in claim 15, further comprising a conducting structure disposed between the redistribution layer and the circuit board, wherein the redistribution layer of the sensing device is exposed.

18. The photosensitive module as claimed in claim 15, wherein the conducting structure is adhesive.

19. The photosensitive module as claimed in claim 15, wherein the sensing device further comprises a second opening, wherein the second opening extends along a sidewall of the substrate and penetrates the substrate.

20. The photosensitive module as claimed in claim 19, wherein the first opening is in communication with the second opening.

21. The photosensitive module as claimed in claim 20, wherein a sidewall portion of the substrate is located between the first opening and the second opening, and a thickness of the sidewall portion is less than that of the substrate.

22. The photosensitive module as claimed in claim 15, wherein the sensing device further comprises a protection layer, wherein the protection layer fills the first opening and the second opening.

23. The photosensitive module as claimed in claim 15, wherein the sensing device further comprises a protection layer, wherein the protection layer partially fills the first opening so that a hole is located between the redistribution layer and the protection layer within the first opening.

24. The photosensitive module as claimed in claim 23, wherein the redistribution layer has an end located within the hole.

25. The photosensitive module as claimed in claim 15, wherein the anti-contamination layer is conformally disposed on the first surface and has an uneven surface.

26. The photosensitive module as claimed in claim 25, wherein the uneven surface of the anti-contamination layer has a plurality of projections.

27. The photosensitive module as claimed in claim 15, wherein the anti-contamination layer comprises an anti-reflective material.

28. The photosensitive module as claimed in claim 15, wherein hardness of the anti-contamination layer is substantially the same as that of glass.
